(19) United States
(12) Patent Application Publication
(10) Pub. No.: US 2025/0023551 A1
(43) Pub. Date: Jan. 16, 2025

(54) JOINT BODY AND ELASTIC WAVE ELEMENT

(71) Applicant: NGK INSULATORS, LTD., Nagoya-shi (JP)

(72) Inventors: Yuki ITO, Nagoya-shi (JP); Taishi TAKAHASHI, Nagoya-shi (JP)

(21) Appl. No.: 18/899,612

(22) Filed: Sep. 27, 2024

Related U.S. Application Data
(63) Continuation of application No. PCT/JP2022/041912, filed on Nov. 10, 2022.

(30) Foreign Application Priority Data
Mar. 30, 2022 (JP) 2022-056518

(51) Int. Cl. H03H 9/25; H03H 9/02

(52) U.S. Cl. CPC H03H 9/25; H03H 9/02559; H03H 9/02574

(57) ABSTRACT

A bonded body has a supporting substrate and a piezoelectric material layer bonded with the supporting substrate. The piezoelectric material layer has a first main surface bonded with the supporting substrate and a second main surface on the opposite side of the first main surface. The piezoelectric material layer has an argon atom-containing layer exposed at the second main surface.

### CROSS-REFERENCE TO RELATED APPLICATIONS

This application is a continuation application of PCT/JP2022/041912, filed Nov. 10, 2022, which claims priority to Japanese Application No. JP 2022-056518 filed on Mar. 30, 2022, the entire contents all of which are incorporated hereby by reference.

### TECHNICAL FIELD

The present invention is related to a bonded body of a piezoelectric material layer and supporting substrate and an acoustic wave element.

### BACKGROUND ARTS

A surface acoustic wave device, which can be functioned for a filter device or vibrator contained in a mobile phone or the like, and an acoustic wave device such as a Lamb wave device or film bulk acoustic resonator (FBAR) including a piezoelectric thin film have been known. It is known an acoustic wave device provided by adhering a supporting substrate and a piezoelectric material substrate propagating surface acoustic wave and by providing a comb electrode capable of oscillating the surface acoustic wave on a surface of the piezoelectric material substrate. The supporting substrate with a thermal expansion coefficient lower than that of the piezoelectric material substrate is adhered to the piezoelectric material substrate as such, so that the change of the size of the piezoelectric material substrate with temperature change is suppressed and the change of the frequency characteristics of the surface acoustic wave element is suppressed.

When such surface acoustic wave element is produced, a piezoelectric material substrate is bonded onto a supporting substrate and the exposed surface of the piezoelectric material substrate is then subjected to grinding and polishing, so that the thickness of the piezoelectric material substrate is reduced to, for example, 20 μm or smaller. It is thereby possible to improve the property of the surface acoustic wave.

### PRIOR ARE DOCUMENTS

### Patent Documents

(Patent document 1) WO 2020-250490 A1

### SUMMARY OF THE INVENTION

However, according to the thus obtained surface acoustic wave element, it is proved that there is a room for improvement of a Q value. There is a room for the improvement particularly in a range of 0.3 to 6.0 GHz.

An object of the present invention is to provide a bonded body capable of improving the Q value of an acoustic wave element.

The present invention provides a bonded body comprising:
a supporting substrate and;
a piezoelectric material layer bonded with said supporting substrate,
wherein said piezoelectric material layer has a first main surface bonded to said supporting substrate, a second main surface opposite to said first main surface and an argon atom-containing layer exposed at said second main surface.

Further, the present invention provides an acoustic wave element comprising:
said bonded body and;
an electrode provided on said second main surface of said piezoelectric material layer.

The present inventors tried to bond a piezoelectric material substrate onto a supporting substrate and to polish the surface (exposed surface) of the piezoelectric material substrate so that the substrate is thinned to form a piezoelectric material layer, and they have variously tried to study the surface state of the piezoelectric material layer. However, the Q value of an acoustic wave could not be considerably improved by changing the degree of the polishing, method of polishing, abrasives or the like.

Then, the present inventors have variously studied the processing methods of the surface of the piezoelectric material substrate and tried ion trimming with argon ion. As a result, a thin processing denatured layer was formed on the surface of the piezoelectric material layer. As an electrode is formed thereon to produce an acoustic wave element, the improvement of the Q value was limited.

As the ratios of the respective atoms in a surface region of such piezoelectric material layer is measured by EDX, it is proved that the ratios of niobium atoms and tantalum atoms in the processing denatured layer of the surface are low and are gradually increased from the surface in the depth direction. Then, as it is reached at the thickness of several nm from the surface of the piezoelectric material layer, the ratios of niobium atoms and tantalum atoms are 30 to 40 atom % and substantially stabilized. It is considered that the crystalline structure of lithium niobate or tantalum niobate are considerably fractured in the vicinity of the surface of the piezoelectric material layer. On the other hand, although argon atoms are not present in the processing denatured layer, it is proved that an argon atom-containing layer containing a relatively large amount of argon atoms is present thereunder. Then, the present inventors tried to remove the processing denatured layer, to expose the argon atom-containing layer, to form an electrode thereon and to produce the acoustic wave element. As a result, it is found that the Q value is considerably improved and the present invention is thus made.

Although the reason why such effects and results are obtained, it is considered that the propagation loss in the surface region of the piezoelectric material layer is reduced by the argon atom-containing layer and the Q value is considerably improved.

### BRIEF DESCRIPTION ON THE DRAWINGS

FIG. 1A is a schematic view showing a bonded body of a supporting substrate 1 and piezoelectric material substrate 2, FIG. 1B is a schematic view showing the state that the piezoelectric material substrate is thinned to form a piezoelectric material layer 2A, and FIG. 1C is a schematic view showing the state that the piezoelectric material layer 2A is subjected to argon ion trimming.

FIG. 2A is a schematic view showing a piezoelectric material layer 2B after the argon ion trimming, FIG. 2B is a schematic view showing a piezoelectric material layer 2C in which an argon atom-containing layer 3 is exposed, FIG. 2C shows a bonded body 7 of the piezoelectric material layer 2C and supporting substrate 1, and FIG. 2D shows an acoustic wave element 8 including an electrode 6 provided on the piezoelectric material layer 2C of the bonded body.

FIG. 3 is a photograph taken by a transmission type electron microscope showing the surface state of the piezoelectric material substrate after the argon ion trimming.

FIG. 4 is a schematic view corresponding with FIG. 3.

FIG. 5 is a graph showing EDX data of a surface region of the piezoelectric material substrate of FIG. 3.

FIG. 6 is a photograph taken by a transmission type electron microscope showing the vicinity of the argon atom-containing layer of the piezoelectric material substrate.

FIG. 7 is a diagram for illustrating the photograph of FIG. 6

FIG. 8 is a graph showing EDX data of the surface region of the piezoelectric material substrate of FIG. 6.

FIG. 9 is a chart showing Sn characteristics in the inventive example 1.

### EMBODIMENT FOR CARRYING OUT THE INVENTION

The present invention will be described further in detail, appropriately referring to the drawings.

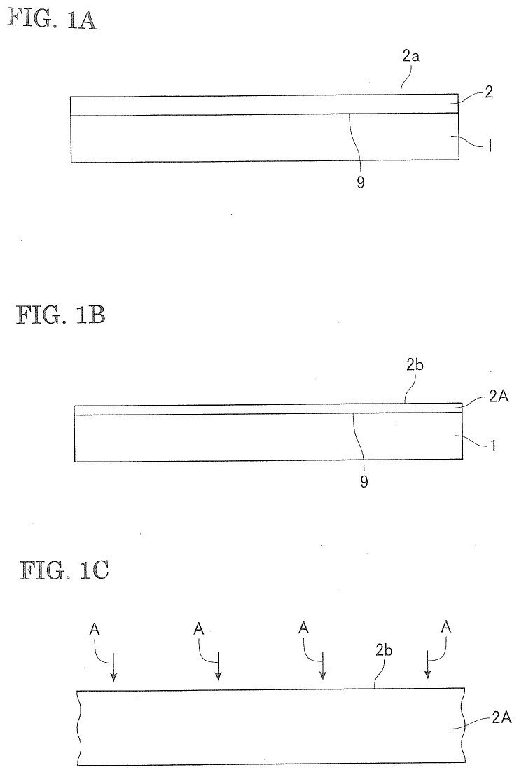

As shown in FIG. 1A, a supporting substrate 1 and piezoelectric material substrate 2 are bonded to provide a bonded body. The piezoelectric material substrate 2 has a first main surface 9 and a second main surface 2a. Then, the second main surface 2a of the piezoelectric material substrate 2 is subjected to polishing process to form a thin piezoelectric material layer 2A as shown in FIG. 1B. 2b represents a polished surface.

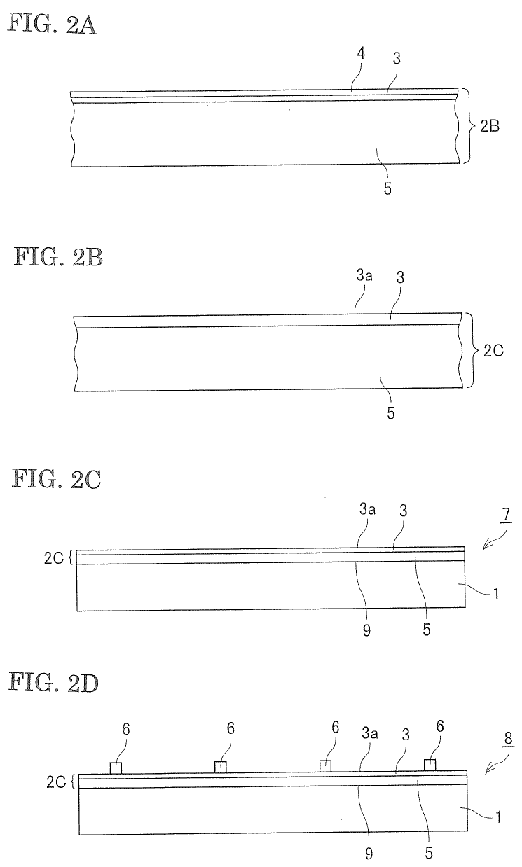

Then, as shown in FIG. 1C, the polished surface 2b of the piezoelectric material layer 2A is subjected to argon ion trimming as arrows A. The piezoelectric layer 2B is thereby generated as shown in FIG. 2A as an enlarged view. A processing denatured region 4 is exposed on the surface of the piezoelectric material layer 2B and an argon atom-containing layer 3 is generated direct under the processing denatured layer 4. A numeral 5 represents a non-denatured region which is not denatured by the processing.

Then, the processing denatured layer 4 is removed by processing to provide a piezoelectric material layer 2C as shown in FIG. 2B. The argon atom-containing layer 3 is generated and exposed on the side of the second main surface 3a of the piezoelectric material layer 2C. A bonded body 7 shown in FIG. 2C is thereby provided. The bonded body 7 is composed of the supporting substrate 1 and the piezoelectric material layer 2C bonded with the supporting substrate 1.

Then, as shown in FIG. 2D, an electrode 6 is formed on the second main surface 3a of the piezoelectric material layer 2C to produce an acoustic wave element 8.

According to the present invention, the supporting substrate may be composed of a single crystal or a polycrystal. The material of the supporting substrate is preferably selected from the group consisting of silicon, sialon, sapphire, cordierite, mullite and alumina. Alumina is preferably a translucent alumina.

Silicon may be a monocrystalline silicon or polycrystalline silicon, and may be a high-resistance silicon. Sialon is a ceramic material obtained by sintering mixture of silicon nitride and alumina and having the following composition.

Si_{6-w}Al_{w}O_{w}N_{8-w}

w may more preferably be 0.5 or higher. Further, w may more preferably be 4.0 or lower.

Sapphire is a single crystal having a composition of Al₂O₃, and alumina is a polycrystal having a composition of A1₂O₃. Cordierite is a ceramic having a composition of 2MgO·2Al₂O₃·5SiO₂. Mullite is a ceramic having a composition of 3Al₂O₃·2SiO₂ to 2Al₂O₃·SiO₂.

Although the material of the piezoelectric material substrate is not limited as far as it has necessary piezoelectricity, a single crystal having a composition of LiAO₃ is preferred. Here, A represents one or more elements selected from the group consisting of niobium and tantalum. Thus, LiAO₃ may be lithium niobate, lithium tantalate or a lithium niobate-lithium tantalate solid solution.

The supporting substrate and piezoelectric material substrate may be directly bonded with each other. The method of the direct bonding may be surface activation by plasma or surface activation method by neutralized atomic beam.

According to a preferred embodiment, one layer or plural layers of the bonding layers may be provided between the piezoelectric material substrate and supporting substrate. As the material of such bonding layer, the followings are exemplified.

SiO₂, Si₍₁₋ᵥ₎Oᵥ (0.008≤v≤0.408), Ta₂O, Al₂O₃, Nb₂O₅, TiO₂

According to the present invention, the piezoelectric material layer has the argon atom-containing layer exposed at the second main surface. Here, the argon atom-containing layer means a layer in which argon atoms are contained in the piezoelectric material.

Specifically, the argon atom-containing layer is defined as a part in which the atomic ratio of argon atoms is 1 atom % or higher when measured by EDX.

Further, the atomic ratio of argon atoms of the argon atom-containing layer is usually 5 atom % or lower in many cases.

According to a preferred embodiment, the thickness of the argon atom-containing layer is 1 to 10 nm and more preferably 3 to 8 nm.

Further, according to a preferred embodiment, the content of argon atoms of the argon atom-containing layer is 5 to 7 atom % in average and is more preferably 7 to 10 atom %.

Further, in the argon atom-containing layer, the atomic ratio (total value) of atoms derived from a material forming the non-denatured region of the piezoelectric material layer is 99.0 to 99.9 atom % in average and more preferably 99.5 to 99.9 atom %. Here, the material forming the non-denatured region of the piezoelectric material layer means a piezoelectric material. In the case that the piezoelectric material is LiAO₃, it is a total value of the atomic ratio of the element A and the atomic ratio of O (the atomic ratio of lithium is not measurable.).

Here, the measurement of the respective atomic ratios by TEM-EDX is to be performed as follows.

First, electron beam is irradiated onto an object to be analyzed. Characteristic X-ray is generated from the object to be analyzed by irradiating the electron beam. As the energy of the characteristic X-ray is unique to the element, the ratios of the respective elements are measured by measuring the kind and number of occurrence of the energy.

The following method is preferred for providing the inventive bonded body.

First, a second main surface of a piezoelectric material substrate is subjected to polishing process to thin the piezoelectric material substrate to provide a piezoelectric material layer. At this time, it is preferred to flatten the main surface by precise polishing process and the method of the flattening may be lapping, chemical mechanical polishing (CMP) or the like. Further, the flatness of the main surface Ra may preferably be 1 nm or lower and more preferably be 0.3 nm or lower.

Then, it is preferred to clean the main surface of the piezoelectric material layer for removing residue of a polishing agent and the processing denatured layer. The method of cleaning the main surface may be wet cleaning, dry cleaning, scrub cleaning or the like, and the scrub cleaning is preferred for providing cleaned surface easily and efficiently.

Then, argon ion trimming is performed on the main surface of the piezoelectric material layer so that the processing denatured layer and argon atom-containing layer can be formed on the side of the main surface of the piezelectric material layer. The argon ion trimming is a technique utilizing the phenomenon of sputtering of colliding Ar atoms accelerated in an electric field onto an object to be processed and of flicking off atoms on the surface of the object to be processed. In this case, Ar ion beam is focused and then collided onto the object to be processed.

Preferred conditions of the argon ion trimming are as follows.
Diameter of focused ion beam: 10 mm or smaller
Acceleration output: 120 W

On the viewpoint of properties of the device, the thickness of the piezoelectric material layer may preferably be 1 μm or smaller and more preferably be 0.5 μm or smaller. Further, the thickness of the piezoelectric material layer may preferably be 0.1 μm or larger, on the viewpoint of the processability.

The applications of the bonded body of the present invention are not particularly limited, and it may be appropriately applied for an acoustic wave element or optical element, for example.

As the acoustic wave element, a surface acoustic wave device, Lamb wave-type device, thin film resonator (FBAR) or the like is known. For example, the surface acoustic wave device is produced by providing input side IDT (Interdigital transducer) electrodes (also referred to as comb electrodes or interdigitated electrodes) for oscillating surface acoustic wave and IDT electrodes on the output side for receiving the surface acoustic wave on the surface of the piezoelectric material substrate. By applying high frequency signal on the IDT electrodes on the input side, electric field is generated between the electrodes, so that the surface acoustic wave is oscillated and propagated on the piezoelectric material substrate. Then, the propagated surface acoustic wave is drawn as an electrical signal from the IDT electrodes on the output side provided in the direction of the propagation.

A metal film may be provided on a bottom surface of the piezoelectric material substrate. After the Lamb type device is produced as the acoustic wave device, the metal film plays a role of improving the electro-mechanical coupling factor near the bottom surface of the piezoelectric material substrate. In this case, the Lamb type device has the structure that interdigitated electrodes are formed on the surface of the piezoelectric material substrate and that the metal film on the piezoelectric material substrate is exposed through a cavity provided in the supporting substrate. Materials of such metal films may be aluminum, an aluminum alloy, copper, gold or the like, for example. Further, in the case that the Lamb wave type device is produced, it may be used a composite substrate having the piezoelectric material layer without the metal film on the bottom surface.

Further, a metal film and an insulating film may be provided on the bottom surface of the piezoelectric material substrate. The metal film plays a role of electrodes in the case that the thin film resonator is produced as the acoustic wave device. In this case, the thin film resonator has the structure that electrodes are formed on the upper and bottom surfaces of the piezoelectric material substrate and the insulating film is made a cavity to expose the metal film on the piezoelectric material substrate. Materials of such metal films may be molybdenum, ruthenium, tungsten, chromium, aluminum or the like, for example. Further, materials of the insulating films include silicon dioxide, phosphorus silicate glass, boron phosphorus silicate glass or the like, for example.

In the case that an object of the present invention is the acoustic wave element and the material of the piezoelectric material substrate is lithium tantalate, it is preferred to use the substrate rotated from Y-axis to Z-axis by 123 to 133° (for example 128°) around X-axis, which is a direction of propagation of a surface acoustic wave, because of a low propagation loss.

Further, in the case that the piezoelectric material substrate is composed of lithium niobate, it is preferred to use the substrate rotated from Y-axis to Z-axis by 86 to 94° (for example 90°) around X-axis, which is the direction of propagation of the surface acoustic wave, because of a low propagation loss. Further, although the size of the piezoelectric material substrate is not particularly limited, for example, the diameter is 50 to 150 mm and thickness is 0.2 to 60 μm.

### EXAMPLES

### Inventive Example 1

A surface acoustic wave element was fabricated according to the method described referring to FIGS. 1 and 2.

Specifically, a lithium niobate substrate (LN substrate) having an OF part, a diameter of 4 inches and a thickness of 250 μm was applied as the piezoelectric material substrate 2. It was used a 42° Y-cut X-propagation LN substrate in which the propagation direction of surface acoustic wave (SAW) was made X and the cutting angle was of rotated Y-cut plate, as the LN substrate. The first main surface 9 of the piezoelectric material substrate 2 was subjected to mirror surface polishing so that the arithmetic average roughness Ra reached 0.3 nm. Further, Ra was measured by an atomic force microscope (AFM) in a visual field of 10 μm×10 μm.

Further, it was prepared the supporting substrate 1 having an orientation flat (OF) part, a diameter of 4 inches and a thickness of 500 μm and composed of silicon (Si (111)), as the supporting substrate 1. The surfaces of the supporting substrate 1 were subjected to finishing by chemical mechanical polishing (CMP), so that the respective arithmetic average roughnesses Ra were 0.2 nm.

Then, plasma is irradiated onto the main surface 9 of the piezoelectric material substrate 2 and surface of the supporting substrate 1 to activate the surfaces, followed by direct bonding.

Then, the main surface 2a of the piezoelectric material substrate 2 was subjected to grinding and polishing until the thickness was changed from the initial 250 μm to 20 μm, to provide a piezoelectric material layer 2A. Argon ion trimming was performed onto the main surface 2b of the piezoelectric material layer 2A according to the following conditions.
Gas flow rate: 6 sccm
Output power: 120 W

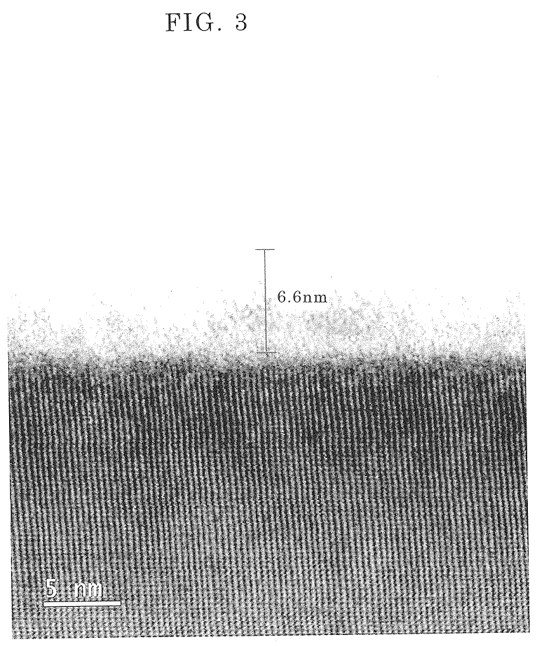

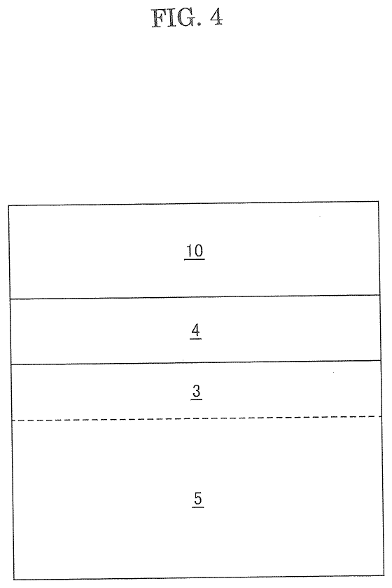

FIG. 3 shows a photograph showing the vicinity of the surface of the thus obtained piezoelectric material layer 2B, and FIG. 4 shows a diagram of the illustration. In FIG. 3, a bright region on the upper side corresponds with a protective film 10, and the non-denatured region 5 of the piezoelectric material layer is present on the lowermost side. The argon atom-containing layer 3 and processing denatured layer 4 are present over the non-denatured layer 5.

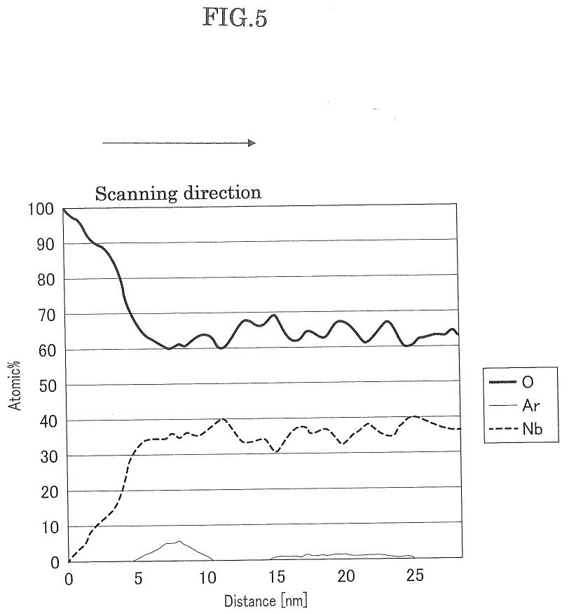

FIG. 5 shows the result of the measurement of the surface region of the piezoelectric material layer shown in FIGS. 3 and 4 by EDX. The horizontal axis indicates a distance from the surface (main surface) of the piezoelectric material layer, and the vertical axis indicates the ratios of oxygen atoms, argon atoms and niobium atoms. The ratio of the oxygen atoms is deacrased from 100 atom % to about 60 atom % from the surface of the piezoelectric material substrate to the depth of about 5 nm, and at the same time, the ratio of niobium atoms is increased from 0 atom % to about 30 atom %. The region corresponds with the processing denatured layer. As the processing denatured layer is generated as the result of the destruction of crystalline structure of lithium niobate, the ratio of niobium is lower and the ratio of oxygen is higher, as it is nearer to the surface. Further, the ratio of lithium atoms was not measured. On the other hand, argon atoms were hardly detected in the range of about 5 nm from the main surface of the piezoelectric material layer.

Further, the argon atom-containing layer having a thickness of 5 nm was formed in a region of about 5 nm to 10 nm from the main surface of the piezoelectric material layer. The content of argon atoms in the argon atom-containing layer is 2 to 6 atom %, and 4 atom % of argon atoms is contained in average. Then, both of the ratios of oxygen atoms and of niobium atoms are stable under the argon atom-containing layer, forming the non-denatured region.

Then, the main surface of the piezoelectric material layer was treated by CMP (Chemical mechanical polishing) to remove the processing denatured layer.

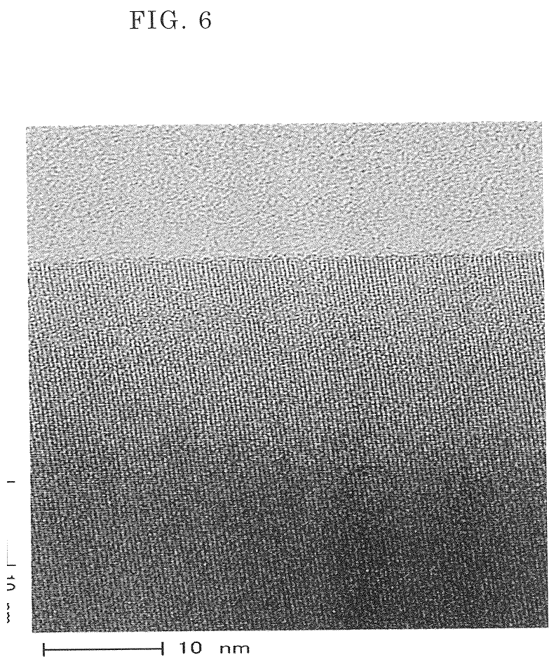

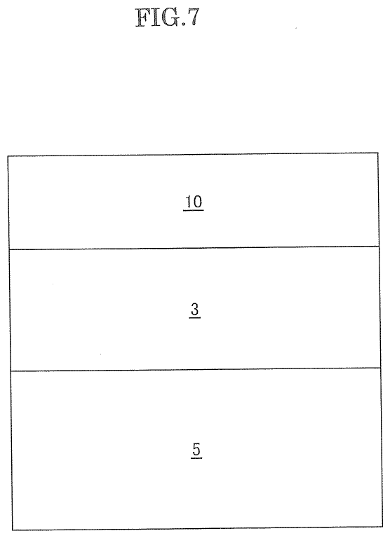

FIG. 6 shows a photograph taken by a transmission type electron microscope of the surface region of the piezoelectric material substrate, and FIG. 7 shows a diagram illustrating FIG. 6. In FIG. 7, a bright region on the upper side corresponds with the protective film 10, and the non-denatured region 5 of the piezoelectric material substrate is present on the lower most side. The argon atom-containing layer 3 is present on the non-denatured region 5. The processing denatured layer is removed.

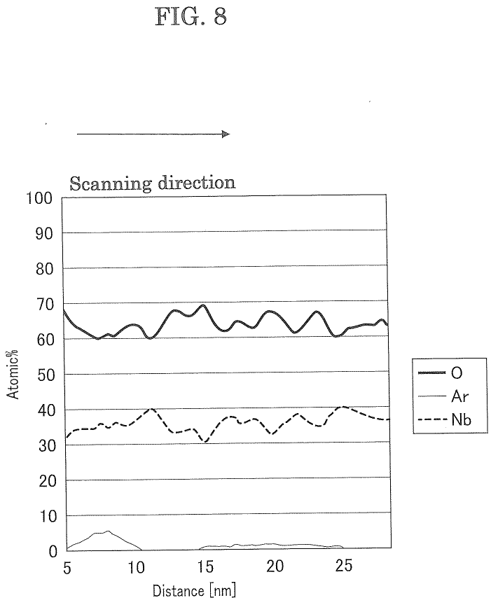

FIG. 8 substantially shows the results of EDS of the surface region. That is, as the processing denatured layer of the piezoelectric material substrate was removed by polishing over about 5 nm, the argon atom-containing layer is exposed at the main surface of the piezoelectric material layer. Thus, argon atoms are contained in the range of about 5 nm from the main surface of the piezoelectric material layer as described above and the non-denatured region is present under the range.

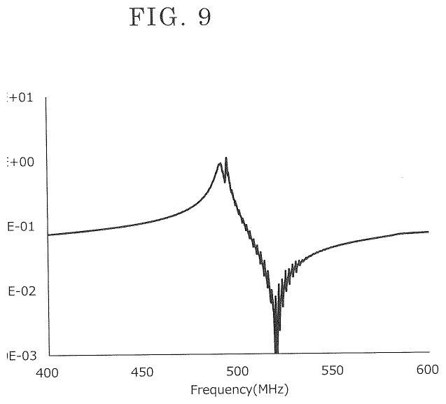

An electrode pattern for measurement was formed on the surface of the argon atom-containing layer of the piezoelectric material layer to provide a surface acoustic wave element. Specifically, SAW (surface acoustic wave) resonator was formed on the surface of the wafer by photolithography. That is, 50 lines of reflectors were provided on both sides of a comb electrode composed of 100 sets of electrode pieces, respectively. The electrode periods of the comb electrode and reflectors were made 5.66 μm, respectively. The frequency characteristics Si was measured by a network analyzer “E5072A” produced by Keysight Corporation. The measurement results were shown in FIG. 9. The resonance frequency fᵣ and the half value width Δfᵣ were calculated from the thus obtained frequency characteristics and fᵣ/Δfᵣ was obtained to provide the Q value.

As the Q value (Bode-Q) was calculated based on the thus obtained S₁₁ parameter, a value of 2800 was obtained as the maximum.

### Inventive Example 2

It was provided a bonded body of a supporting substrate and piezoelectric material layer whose argon atom-containing layer is exposed on the side of the second main surface as the inventive example 1. Further, according to the inventive example 2, different from the inventive example 1, the output power for the accelerating condition of argon ions during the argon ion trimming was made 60 W.

As the surface region of the piezoelectric material layer was subjected to EDX analysis, the argon atom-containing layer was generated in the range of 4 nm from the main surface. Further, the maximum value and average value of the ratio of argon atoms were 3 atom % and 2 atom %, respectively.

As the bonded body was applied to produce the surface acoustic wave element as the inventive example 1 and the Q value was measured, it was proved to be 2400 at the maximum.

### Comparative Example 1

A bonded body of a piezoelectric material layer and supporting substrate was provided as the inventive example 1. However, according to the comparative example 1, different from the inventive example 1, the argon ion trimming of the main surface of the piezoelectric material layer was not performed. Thus, lithium niobate was exposed at the main surface of the piezoelectric material layer, and the processing denatured layer and argon atom-containing layer were not generated.

As the bonded body was applied to produce the surface acoustic element as the inventive example 1 and the Q value was measured, the maximum value of 1800 was obtained.

### Comparative Example 2

A bonded body of a piezoelectric material layer and supporting substrate was provided as the inventive example 1. Here, according to the comparative example 2, the argon ion trimming of the main surface of the piezoelectric material layer was performed as the inventive example 1 under the same conditions. However, the polishing was not performed after the ion trimming. Thus, the processing denatured layer which does not contain argon atoms was generated on the main surface of the piezoelectric material layer.

As the bonded body was applied to produce the surface acoustic wave element as the inventive example 1 and Q value was measured, the maximum value of 1150 was obtained.

1. A bonded body comprising:
a supporting substrate; and
a piezoelectric material layer bonded with said supporting substrate,
wherein said piezoelectric material layer comprises a first main surface bonded with said supporting substrate, a second main surface opposite to said first main surface and an argon atom-containing layer exposed at said second main surface.

2. The bonded body of claim 1, wherein said argon atom-containing layer has a thickness of 1 to 10 nm.

3. The bonded body of claim 1, wherein said argon atom-containing layer has an average content of argon atoms of 1 to 10 atom %.

4. The bonded body of claim 1, wherein said piezoelectric material layer comprises lithium niobate, lithium tantalate or lithium niobate-lithium tantalate.

5. An acoustic wave element comprising:
the bonded body of claim 1, and
an electrode provided on said second main surface of said piezoelectric material layer.
